(19) United States
(12) Patent Application Publication
(10) Pub. No.: US 2023/0382756 A1
(43) Pub. Date: Nov. 30, 2023

(54) MIXED METAL OXIDE INCLUDING MAGNESIUM AND ZINC

(71) Applicant: IMEC VZW, Leuven (BE)

(72) Inventors: Michiel Jan Van Setten, Heverlee (BE); Geoffrey Pourtois, Villers-la-Ville (BE); Hendrik F.W. Dekkers, Tienen (BE); Gouri Sankar Kar, Leuven (BE)

(21) Appl. No.: 18/324,791

(22) Filed: May 26, 2023

(30) Foreign Application Priority Data
May 31, 2022 (EP) 22176406.1

(51) Int. Cl. C01G 9/03; H01L 29/786

(52) U.S. Cl. CPC C01G 9/03; H01L 29/78693; C01P 2002/02

(57) ABSTRACT

A mixed metal oxide and methods for making the mixed metal oxide are disclosed. The mixed metal oxide includes metal and metalloid elements including 0.40 to 0.70 parts by mole Mg, 0.30 to 0.60 parts by mole Zn, and 0.00 to 0.30 parts by mole of other elements selected from metals and metalloids, wherein less than 0.01 parts by mole of the other elements is Al, and wherein less than 0.04 parts by mole of the other elements is Ga. The sum of all parts by mole of Mg, Zn, and the other elements may amount to about 1.00. The mixed metal oxide additionally includes) oxygen and less than 0.01 parts by mole of non-metallic and non-metalloid impurities.

### CROSS-REFERENCE TO RELATED APPLICATIONS

This application claims foreign priority to European Application No. 22176406.1, filed May 31, 2022, the content of which is incorporated by reference herein in its entirety.

### BACKGROUND

### Technological Field

The disclosed technology generally relates to mixed metal oxides, and more in particular to mixed metal oxides including Mg and Zn for thin-film transistors (TFT).

### Description of the Related Technology

Thin film transistors are widely used in displays, memory, and logic devices. Due to their possibly intensive long-term use, TFTs typically comprise chemically stable materials. In particular, the material for the channel of a TFT is typically chosen to enable high on-currents and low off-currents, that is, a high current in the on-state and a low current in the off-state.

The typical process for forming TFTs is during the back-end-of-line (BEOL) stage of integrated circuit fabrication. Furthermore, in the particular application of three-dimensional (3D) devices such as 3D memory devices, devices comprising transistors (for example, thin film transistors) may be stacked to form the 3D device. In the process of forming a new device such as a memory cell above an existing one, temperatures above 400° C. are usually avoided so as not to substantially alter any already formed devices. However, such deposition temperatures can severely limit the type of materials that may be deposited for TFTs. Many materials typically used as channel material may crystallize at higher crystallization temperatures, which may render them less attractive for use in TFTs.

In contrast, the deposition of amorphous materials may be formed at temperatures lower than these high thermal treatments. However, the resulting films of amorphous materials can be associated with significantly lower charge carrier mobilities than their crystalline counterparts. Moreover, to be compatible with silicon technology, the materials are preferably chemically stable during a forming gas annealing process. Amorphous materials may be less stable, for example, less chemically stable than their crystalline counterparts.

One amorphous oxide known in the industry, the metal oxide a-InGaZnO₄ or amorphous InGaZnO₄, (referred to herein as IGZO) has comparatively good electron mobility versus typical amorphous oxides. Without being bound to a single theory of operation, this relatively good electron mobility may be due to the interaction of s and d orbitals of the metal cations in a lower part of the conduction band. The strength of the bonds between the cations, and, in addition, the type of cations, may drive the effective mobility of the system. The electron mobility of IGZO and its chemical stability may still, however, not be sufficiently high for some applications. IGZO has a relatively low electron mobility (approximately 20 to 35 cm²/(V·s)) and low chemical stability.

There is therefore a need in the art for a material and method for forming the material that solves one or more of the above problems.

### SUMMARY OF CERTAIN INVENTIVE ASPECTS

The disclosed technology is directed, in part, to a mixed metal oxide of Mg and Zn. The disclosed technology also provides a method for forming the mixed metal oxide, and a transistor comprising the mixed metal oxide.

The disclosed technology provides several advantages, such as a mixed metal oxide with good electron mobility. The disclosed technology may also provide a channel of a transistor comprising a mixed metal oxide that exhibits high current in the on-state, and low current in the off-state.

The disclosed technology provides for a mixed metal oxide with favourable chemical stability. The disclosed technology provides for a mixed metal oxide with good stability against annealing in a forming gas atmosphere. This property of stability may increase the compatibility of the mixed metal oxide with a step that is often performed in semiconductor manufacturing processes.

According to the disclosed technology, the elements making up a mixed metal oxide may be non-toxic. Similarly, the elements making up a mixed metal oxide may be compatible with standard industrial silicon technology.

According to the disclosed technology, a mixed metal oxide may be deposited at temperatures below 400° C. In some embodiments, a mixed metal oxide may be deposited in the BEOL stage of semiconductor manufacturing processing. By way of a non-limiting example, silicon devices, such as silicon logic gates, may degrade at temperatures above 400° C., and a mixed metal oxide according to the disclosed technology may be deposited at or below 400° C.

According to the disclosed technology, a mixed metal oxide may have good properties for use of the mixed metal oxide in transistors, such as in TFTs. In some embodiments, a mixed metal oxide may have good properties for use as channel material in a TFT.

In a first aspect, the disclosed technology relates to an amorphous mixed metal oxide including:
a) a mixture including about 0.40 to 0.70 parts by mole Mg, 0.30 to 0.60 parts by mole Zn, and 0.00 to 0.30 parts by mole of other elements selected from metals and metalloids,
wherein less than about 0.01 parts by mole of the other elements is Al,
wherein less than about 0.04 parts by mole of the other elements is Ga,
wherein the sum of all parts by mole of Mg, Zn, and the other elements amounts to 1.00,
b) oxygen, and
c) less than about 0.01 parts by mole of non-metallic and non-metalloid impurities.

The disclosed technology further relates to an amorphous mixed metal oxide including:
a) metal or metalloid elements including about 0.40 to 0.70 parts by mole Mg, 0.30 to 0.60 parts by mole Zn, and 0.00 to 0.30 parts by mole of other elements selected from metals and metalloids,
wherein less than about 0.01 parts by mole of the other elements is Al,
wherein less than about 0.04 parts by mole of the other elements is Ga,
wherein the sum of all parts by mole of Mg, Zn, and the other elements amounts to 1.00,
b) oxygen, and
c) less than about 0.01 parts by mole of non-metallic and non-metalloid impurities.

In some embodiments, an amorphous mixed metal oxide may consist essentially of the above recited elements. In some embodiments, an amorphous mixed metal oxide may consist of the above recited elements. In some embodiments, the mixture of amorphous mixed metal oxide may consist essentially of about 0.40 to 0.70 parts by mole Mg, 0.30 to 0.60 parts by mole Zn, and 0.00 to 0.30 parts by mole of other elements selected from metals and metalloids. In some embodiments, the mixture of amorphous mixed metal oxide may consist of about 0.40 to 0.70 parts by mole Mg, 0.30 to 0.60 parts by mole Zn, and 0.00 to 0.30 parts by mole of other elements selected from metals and metalloids.

In some embodiments, the parts by mole of the components of the mixed metal oxide may be measured by Rutherford Backscattering Spectroscopy. In some embodiments, the parts by mole may be measured by other non-destructive or destructive techniques. In some embodiments, the parts by mole of one analytical technique may yield similar but not identical values as measured by Rutherford Backscattering Spectroscopy, and a conversion between the two measurements may be established.

In a second aspect, the disclosed technology relates to a method for forming the oxide according to any embodiment of the first aspect, including the step(s) of depositing a magnesium oxide, a zinc oxide, and optionally one or more other oxides selected from metal oxides and metalloid oxides on a substrate, so as to form a mixed metal oxide, where the mixed metal oxide includes:
a) metal and metalloid elements including 0.40 to 0.70 parts by mole Mg, 0.30 to 0.60 parts by mole Zn, and 0.00 to 0.30 parts by mole of other elements selected from metals and metalloids,
wherein less than 0.01 parts by mole of the other elements is Al,
wherein less than 0.04 parts by mole of the other elements is Ga,
wherein the sum of all parts by mole of Mg, Zn, and the other elements amounts to 1.00,
b) oxygen, and
c) less than 0.01 parts by mole of non-metallic and non-metalloid impurities.

In some embodiments, an amorphous mixed metal oxide may consist essentially of the above recited elements. In some embodiments, an amorphous mixed metal oxide may consist of the above recited elements. In some embodiments, the mixture of amorphous mixed metal oxide may consist essentially of about 0.40 to 0.70 parts by mole Mg, 0.30 to 0.60 parts by mole Zn, and 0.00 to 0.30 parts by mole of other elements selected from metals and metalloids. In some embodiments, the mixture of amorphous mixed metal oxide may consist of about 0.40 to 0.70 parts by mole Mg, 0.30 to 0.60 parts by mole Zn, and 0.00 to 0.30 parts by mole of other elements selected from metals and metalloids.

In a third aspect, the disclosed technology relates to a transistor comprising the oxide according to any embodiment of the first aspect.

Particular aspects of the disclosed technology are described throughout the disclosure. Features from any particular embodiment may be combined with features of other embodiments as appropriate and not merely as explicitly set out in the claims.

Although there has been constant improvement, change, and evolution of devices in this field, the present concepts are believed to represent substantial new and novel improvements, including departures from prior practices, resulting in more efficient, stable, and reliable devices.

The above and other characteristics, features, and advantages of the disclosed technology will become apparent from the following detailed description, taken in conjunction with the accompanying drawings, which illustrate, by way of example, the principles of the disclosed technology. This description is given for the sake of example only, without limiting the scope of the invention. The reference FIGURE and reference numbers quoted herein refer to the attached drawings.

### BRIEF DESCRIPTION OF THE DRAWINGS

FIG. 1 is a schematic representation of a combinatorial physical vapor deposition system.

### DETAILED DESCRIPTION OF CERTAIN ILLUSTRATIVE EMBODIMENTS

The disclosed technology is described with respect to particular embodiments and with reference to certain drawings, but the disclosed technology is not limited thereto. The drawings described are only schematic and are non-limiting. In the drawings, the size of some of the elements may be exaggerated and not drawn on scale for illustrative purposes.

Furthermore, the terms first, second, third, and the like in the description and in the claims, are used for distinguishing between similar elements and not necessarily for describing a sequence, either temporally, spatially, in ranking, or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps, or components, or groups thereof. The term “comprising” therefore covers the situation where only the stated features are present and the situation where these features and one or more other features are present. The word “comprising” according to the invention therefore also includes as one embodiment that no further components are present. Thus, the scope of the expression “a device comprising means A and B” should not be interpreted as being limited to devices consisting only of components A and B. It means that with respect to the disclosed technology, the relevant components of the device are A and B.

All numbers expressing quantities of ingredients, reaction conditions, and so forth used in the specification are to be understood as being modified in all instances by the term ‘about.’ Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

Reference throughout this specification to “one embodiment” or “an embodiment” means that a particular feature, structure, or characteristic described in connection with the embodiment is included in at least one embodiment of the disclosed technology. Thus, appearances of the phrases “in one embodiment” or “in an embodiment” in various places throughout this specification are not necessarily all referring to the same embodiment but can refer to a particular embodiment or combination of embodiments. Furthermore, the particular features, structures, or characteristics may be combined in any suitable manner, as would be apparent to one of ordinary skill in the art from this disclosure, in one or more embodiments.

Similarly, it should be appreciated that in the description of exemplary embodiments of the invention, various features of the invention are sometimes grouped together in a single embodiment, FIGURE, or description thereof for the purpose of streamlining the disclosure and aiding in the understanding of one or more of the various inventive aspects. This method of describing the disclosed technology, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this disclosed technology.

Furthermore, while some embodiments described herein include some but not other features included in other embodiments, combinations of features of different embodiments are meant to be within the scope of the disclosed technology, and form different embodiments, as would be understood by those in the art. For example, in the following description, the embodiments may be used in any combination.

In the description provided herein, numerous specific details are set forth. However, it is understood that embodiments of the invention may be practiced without these specific details. In other instances, well-known methods, structures, and techniques have not been shown in detail in order not to obscure an understanding of this description.

Reference will be made to transistors. These are devices having a first main electrode such as a drain, a second main electrode such as a source, a channel connecting the drain and the source, and a control electrode such as a gate for controlling the flow of electrical charges between the first and second main electrodes, through the channel.

In the context of the disclosed technology, unless otherwise stated, when an amount, for example, in parts by mole, of an element is mentioned, the amount is as measured by Rutherford Backscattering Spectroscopy.

In the context of the disclosed technology, a metalloid may be understood to be an element including arsenic, tellurium, germanium, silicon, antimony, and boron.

In a first aspect, the disclosed technology relates to an amorphous mixed metal oxide including:
a) metal or metalloid elements, which may be distributed throughout the metal oxide to form a mixture (“mixture ‘A’”) with oxygen, including about 0.40 to 0.70 parts by mole Mg, 0.30 to 0.60 parts by mole Zn, and 0.00 to 0.30 parts by mole of other elements selected from metals and metalloids,
wherein the sum of all parts by mole of Mg, Zn, and the other elements amounts to 1.00,
wherein less than about 0.01 parts by mole of the other elements is Al,
wherein less than about 0.04 parts by mole, preferably less than 0.01 parts by mole of the other elements is Ga,
b) oxygen, and
c) less than about 0.01 parts by mole of non-metallic and non-metalloid impurities.

In some embodiments, the mixture “A” may include 0.40 to 0.70 parts by mole Mg, where the Mg refers to the parts by mole of Mg cations in the mixed metal oxide. In some embodiments, the mixture “A” may include 0.30 to 0.60 parts by mole Zn, where the Zn refers to the parts by mole of Zn cations in the mixed metal oxide.

In some embodiments, the mixture “A” may include 0.00 to 0.30 parts by mole of other elements selected from metals and metalloids, where the other elements may be parts by mole of cations in the mixed metal oxide. In some embodiments, the mixture “A” may include less than about 0.01 parts by mole of Al, where the Al refers to the parts by mole of Al cations in the mixed metal oxide. In some embodiments, the mixture “A” may include less than about 0.04 parts by mole, preferably less than 0.01 parts by mole of Ga, where the Ga refers to the parts by mole of Ga cations in the mixed metal oxide. In some embodiments, the mixed metal oxide may include oxygen in the form of oxygen anions in the mixed metal oxide. In some embodiments, the parts by mole are as measured by Rutherford Backscattering Spectroscopy.

Surprisingly, mixed metal oxides of the disclosed technology may have a combination of good electrical conductivity, and good stability. In some embodiments, the good stability of mixed metal oxides of the disclosed technology includes good chemical stability. Without being bound by any theory, the mixed metal oxide having the disclosed amounts of Mg, Zn, and other elements selected from metals and metalloids according to the disclosed technology results in a conduction band that is strongly delocalized over cation sites within the mixed metal oxide, similar to a conduction band of a-InGaZnO₄. This delocalization results in good electrical conductivity. Furthermore, the mixed metal oxides of the disclosed technology have a preferred bandgap that is similar to, or slightly larger than, the bandgap of a-InGaZnO₄. Thereby, when, for example, the mixed metal oxide is used as a channel in a transistor, a current through the channel in an off-state of the transistor may be small. Similar to a-InGaZnO₄, doping of the mixed metal oxide may be induced by an oxygen deficit, compared to a stoichiometric amount of oxygen, in the mixed metal oxide.

In some embodiments, a mixture “A” may include about 0.45 to 0.65 parts by mole Mg, 0.35 to 0.55 parts by mole Zn, and 0.00 to 0.20 parts by mole of other elements.

In some embodiments, a mixture “A” may include about 0.50 to 0.60 parts by mole Mg, 0.40 to 0.50 parts by mole Zn, and 0.00 to 0.10 parts by mole of other elements.

In some embodiments, a mixture “A” may include about 0.53 to 0.57 parts by mole Mg, 0.43 to 0.47 parts by mole Zn, and 0.00 to 0.04 parts by mole of other elements as defined in any embodiments of the first aspect.

In some embodiments, the amount of the other elements other than Mg and Zn, selected from metals and metalloids in a mixture “A” is from about 0.00 to 0.20 parts by mole, such as from 0.00 to 0.10 parts by mole, preferably from 0.00 to 0.05 by mole. In some embodiments of the disclosed technology the elements other than Mg and Zn, selected from metals and metalloids may be advantageously present in low amounts. In some embodiments, when the elements other than Mg and Zn, selected from metals and metalloids are present in low amounts the electrical properties of the mixed metal oxide may be comparable to the good electrical properties and good stability of a similar mixed metal oxide but where the other elements are absent.

In some embodiments, less than about 0.001 parts by mole of the other elements is Al. Most preferably, no Al is present. In some embodiments, no Al is present when Al is not detected by Rutherford Backscattering Spectroscopy. In some embodiments, Al is absent when substantially no Al is detected by Rutherford Backscattering Spectroscopy.

In some embodiments, less than 5 parts by mole, preferably less than 1 parts by mole, more preferably less than 0.1 part by mole, yet more preferably less than 0.01 part by mole, even more preferably less than 0.001 part by mole of the other elements is Ga. Most preferably no Ga is present. In some embodiments, no Ga is present when Ga is not detected by Rutherford Backscattering Spectroscopy. In some embodiments, Ga is absent when substantially no Ga is detected by Rutherford Backscattering Spectroscopy.

In some embodiments, the oxygen is present in an amount that is within 10 mole-%, preferably within 2 mole-%, such as within 1 mole-% of, most preferably equal to, a stoichiometric amount for a metal single oxide. In some embodiments, the amount of oxygen, in moles, in the mixed metal oxide is within 10 mole-%, preferably within 2 mole-%, such as within 1 mole-% of, most preferably equal to, the sum, in moles, of the stoichiometric amount of oxygen with respect to each metal, and possibly each metalloid, in the mixture. In other words, the combination of the mixture a) and the oxygen b) of the mixed metal oxide primarily includes ZnO, MgO, and possibly one or more other stoichiometric metal oxides and/or one or more stoichiometric metalloid oxides, except for a possible margin of up to 10 mole-%, preferably up to 2 mole-%, such as 1 mole-%, in the amount of oxygen. In some embodiments, oxygen is present in an amount in parts per mole that is within 10 mole-%, preferably within 2 mole-%, such as within 1 mole-% of, preferably equal to, the sum, in moles, of the amount of Zn, and the amount of Mg. In this last embodiment, the mixed metal oxide may additionally contain oxygen due to oxides of the other elements selected from metals and metalloids. Without being bound to theory, one contemplated advantage is that the presence of oxygen according to the disclosed technology may facilitate the deposition of the mixed metal oxide at a low temperature.

In some embodiments, the elements of the mixture including Zn, Mg, and, if present, the other elements selected from metals and metalloids, are randomly mixed. Here randomly mixed refers to a random distribution of elements through the mixed metal oxide. Preferably, the mixture is homogeneous. In some embodiments, the oxides of Zn, Mg, and, if present, the other elements selected from metals and metalloids, and possibly any impurities, are randomly mixed in the mixed metal oxide. That is, preferably, the oxides of Zn and Mg are randomly mixed. The mixed metal oxide preferably forms a homogeneous material. It is an advantage of these embodiments that each component of the mixed metal oxide contributes homogeneously, throughout the mixed metal oxide, to the electrical properties of the material. Thereby, the properties of the mixed metal oxide may be homogeneous.

In some embodiments, the mixed metal oxide is in an amorphous phase. The disclosed technology may not substantially crystallize the mixed metal oxide. In general, crystallization may occur at relatively high temperatures for BEOL processing, such as temperatures above 400° C.

In some embodiments, the bandgap of the mixed metal oxide may be a maximum of about 0.6 eV higher and a minimum of about 0.3 eV higher than the bandgap of a-InGaZnO₄. This relative positioning of the band gap may advantageously allow the mixed metal oxide to remain transparent in the visible region of the electromagnetic spectrum. Preferably, the mixed metal oxide is transparent in the visible region of the electromagnetic spectrum.

In some embodiments, the mixed metal oxide contains less than 0.001 parts by mole of non-metallic and non-metalloid impurities. In preferred embodiments, the mixed metal oxide contains less than 0.0005 parts by mole of each non-metallic and non-metalloid impurity. By way of a non-limiting example, a non-metallic and non-metalloid impurity might include hydrogen. Mixed metal oxides according to the disclosed technology may have high purity and thus may also have good and homogeneous electrical properties.

Any features of any embodiment of the first aspect may be independently combined with any of the other aspects of the disclosed technology.

In a second aspect, the disclosed technology relates to a method for forming the oxide according to embodiments of the first aspect, including depositing a magnesium oxide, a zinc oxide, and optionally one or more other oxides selected from metal oxides and metalloid oxides on a substrate, so as to form a mixed metal oxide. Methods of the disclosed technology may include one or more deposition steps. In some embodiments, the mixed metal oxide includes:
a) a mixture including about 0.40 to 0.70 parts by mole Mg, 0.30 to 0.60 parts by mole Zn, and 0.00 to 0.30 parts by mole of other elements selected from metals and metalloids,
wherein less than about 0.01 parts by mole of the other elements is Al,
wherein less than about 0.04 parts by mole, preferably less than 0.01 parts by mole of the other elements is Ga,
wherein the sum of all parts by mole of Mg, Zn, and the other elements amounts to 1.00,
b) oxygen, and
c) less than about 0.01 parts by mole of non-metallic and non-metalloid impurities,
wherein the parts by mole are as measured by Rutherford Backscattering Spectroscopy.

In some embodiments, the deposition is performed at a temperature of at most 400° C., preferably in a temperature range of from about 200° C. to about 400° C. It is an advantage of embodiments of the disclosed technology that the mixed metal oxide may be deposited in the BEOL stage of a manufacturing process of a semiconductor structure, and with forming stacks of transistors, for example, in the manufacturing process of 3D memory devices, without damaging other components of the semiconductor structure. In some embodiments, the substrate includes a semiconductor device.

In some embodiments, the magnesium oxide, the zinc oxide, and the optional one or more other oxides selected from metal oxides and metalloid oxides are deposited using physical vapour deposition. In some embodiments, physical vapour deposition may result in a homogenous, uniform mixture of the oxides. Physical vapour deposition may be compatible with the BEOL stage of semiconductor manufacturing, and with forming 3D memory devices. In some embodiments, the substrate includes silicon. In some embodiments, the substrate includes a monocrystalline silicon wafer.

In physical vapor deposition, a metal or metal oxide target inside a vacuum system may be used as a source for one or more elements of the mixed metal oxide. Physical sputtering may use ionized gases (such as Ar) to move material from the target to the substrate. Typically, when a metal oxide target is used, an AC potential field is applied to the metal oxide target at a frequency of from 100 kHz to 10 MHz.

Typically, when a metal target is used, a pulsed DC potential field is applied to the metal target.

In preferred embodiments, the physical vapour deposition is performed by sputtering simultaneously or co-sputtering a magnesium (or magnesium oxide) target and a zinc oxide target. If a magnesium target is used, the sputtering is preferably performed under an oxygen flow. In some embodiments, an AC potential field is applied to the zinc oxide target at a frequency of from 100 kHz to 10 MHz and a pulsed DC potential field is applied to the magnesium target.

It is an advantage of these embodiments that the deposition of the metal oxides may be efficient. When other elements selected from metal and metalloids are present in the mixture, the deposition of the oxides of these other elements may be performed by sputtering using a corresponding metal or metalloid target or using a corresponding metal oxide or metalloid oxide target.

In other embodiments, the magnesium oxide, the zinc oxide, and optionally one or more other oxides that are selected from metal oxides and metalloid oxides may be deposited using atomic layer deposition.

Any features of any embodiment of the second aspect may be independently as correspondingly described for any embodiment of any of the other aspects of the disclosed technology.

In a third aspect, the disclosed technology relates to a transistor comprising the oxide according to embodiments of the first aspect.

In some embodiments, the oxide according to embodiments of the first aspect forms a channel layer. It is an advantage of these embodiments that a charge mobility in the on-stage of the transistor may be high. It is an advantage of these embodiments that a charge mobility in the off-stage of the transistor may be low.

In some embodiments, the transistor is a thin film transistor. In some embodiments, the thin film transistor includes the mixed metal oxide over a substrate. The mixed metal oxide may serve as a channel of the transistor. In some embodiments, the substrate may be or include a polymer, a glass, and a silicon substrate. The substrate can be flexible or rigid. In some embodiments, the thin film transistor includes a gate material over the substrate. In some embodiments that gate material may be indium tin oxide. In some embodiments, the gate material may be over or directly on the substrate.

The substrate may comprise a semiconductor device. Preferably, the mixed metal oxide is located over the gate material, or the gate material is located over the mixed metal oxide. The gate material is typically separated from the mixed metal oxide by an insulator material, such as SiO2, Al₂O₃, silicon nitride, or HfO₂. The mixed metal oxide typically contacts a drain and a source electrode, which preferably comprise a metal. The process for making thin-film transistors, for example, the channels of thin-film transistors, typically employs particularly low temperatures of formation. It is an advantage of embodiments of the disclosed technology that the combination of good charge mobility, low formation temperature, and chemical stability, may make the oxide according to embodiments of the disclosed technology particularly well-suited for applications in thin-film transistors.

Any features of any embodiment of the third aspect may be independently combined with any of the other aspects of the disclosed technology.

The disclosed technology will now be described by a detailed description of several embodiments of the invention. It is clear that other embodiments of the invention can be configured according to the knowledge of persons skilled in the art without departing from the technical teaching of the disclosed technology.

### Example 1: Theoretical Calculations

First principles theoretical calculations, within the framework of a density functional theory, for example, the Perdew-Burke-Ernzerhof (PBE) density functional theory revised for solids (“PBEsol functional”), were performed to assess the electrical properties and the stability of a range of mixed metal oxides. Herein, the electrical properties are defined by the magnitude of the bandgap, and the inverse state weighted overlap (ISWO) parameter. The ISWO parameter may define the overlap of orbitals between atoms in a material. A low ISWO value represents a delocalized molecular orbital, whose atomic orbitals are continuously connected between the different atomic sites. A high ISWO value represents a highly localized and poorly connected molecular orbital. The ISWO parameter, and how it may be calculated, is further described in A. de Jamblinne de Meux et al., Method to quantify the delocalization of electronic states in amorphous semiconductors and its application to assessing charge carrier mobility of p-type amorphous oxide semiconductors, Physical Review B 97 (2018) 045208.

In this example, calculations were performed for primary oxides (one metal and one oxygen), and binary oxides (two metals and one oxygen), and amorphous oxides. The calculations were performed for 12 metals and metalloids (Mg, Al, Si, Ti, Zn, Ga, Zr, Ag, Cd, In, Sn, and Sb). Machine learning (support vector machines) was used to develop predictor functions for oxides containing up to all 12 elements and oxygen. A single objective function F(x) (shown below) was developed, that, when minimized, predicts promising materials. By varying the weights and target gap in the objective function, mixed metal oxides including Mg and Zn as metals were found to have promising properties. Herein below, results are shown for an amorphous mixed metal oxide consisting of Zn, Mg, and oxygen in a stoichiometric amount, as a function of the amount of Zn and Mg in the mixed metal oxide. Reference is made to Table A. Preferably, the ISWO of the conduction band is as low as possible. A low ISWO for the conduction band may correspond to a continuous molecular orbital for the conduction band, and a potentially high charge mobility in the conduction band. A transistor channel including a material having a low ISWO for the conduction band, may result in a high current through the channel for an on-state of the transistor. Although the best results are obtained when some Al is present, the disclosed technology focuses on alternatives to MgZnAl oxides where very little or no Al is present. Materials with little or no Al present may be advantageous because these materials may have simplified deposition processes. When Al is absent, the lowest ISWO for the conduction band is found for mixed metal oxides having the composition Mg_{0.42}Zn_{0.58}.

Preferably, the ISWO of the valence band is as high as possible. A high ISWO for the valence band may correspond to a discontinuous molecular orbital for the valence band, and a potentially low charge mobility in the valence band. For a transistor channel consisting of a material having a high ISWO for the valence band, there may be a low current through the channel in an off-state of the transistor. A high ISWO for the valence band is found for mixed metal oxides including mostly Mg.

Preferably, the bandgap of the mixed metal oxide is similar to, or slightly higher than the bandgap of a-InGaZnO₄. In some embodiments, a slightly higher bandgap may be a bandgap that is 1 eV higher than the bandgap of a-InGaZnO₄. The bandgap may be observed to increase with increasing amounts of Mg. For a transistor comprising a channel, and the channel comprising the mixed metal oxide, a large bandgap for the mixed metal oxide indicates that the charge mobility may be low in the off state, and high in the on-state of the transistor. While larger bandgaps may enable high on current/off current ratio, doping may be increasingly difficult for larger bandgaps.

It may also be observed that the energy of formation reduces, and, correspondingly, the stability increases, with increasing amount of Mg in the mixed metal oxide.

To find an optimum with respect to material properties, four parameters are defined. Herein, a bandgap is defined with respect to the bandgap of a-InGaZnO₄, i.e., Δ-gap=G(x). Furthermore, an ISWO of the conduction band of the mixed metal oxide is defined with respect to an ISWO of the conduction band of a-InGaZnO₄, i.e., Δ-ISWO_{C}=I_{c}(x). In addition, an ISWO of the valence band of the mixed metal oxide is defined with respect to the ISWO of the valence band of a-InGaZnO₄, i.e., Δ-ISWO_{V}=Iᵥ(x). Finally, a relative energy of formation of the mixed metal oxide is provided that is the difference between: the energy of formation with respect to the energy of formation of isolated atoms of the mixed metal oxide in the gas phase; and the energy of formation with respect to the energy of formation of isolated atoms of a-InGaZnO₄ in the gas phase. The relative energy of formation is given as Δ-E_{form}=E_{f}(x). Herein, a negative value means that the mixed metal oxide is calculated to be more stable than a-InGaZnO₄. Herein, x refers to the amounts of Al and Mg in the mixed metal oxide.

TABLE A
Calculated Electronic Properties, And Formation
Energies, For a Range of Compositions

| | Δ-gap = | Δ-ISWO_{C} = | Δ-ISWO_{V} = | Δ-E_{form} = |
|---|---|---|---|---|
| Metal content | G (x) | I_{c} (x) | Iᵥ (x) | E_{f} (x) |
| Mg0.39Zn0.61 | 0.31 | −0.91 | −0.99 | −0.34 |
| Mg0.41Zn0.58 | 0.36 | −0.94 | −0.8 | −0.38 |
| Mg0.44Zn0.56 | 0.37 | −0.93 | −0.56 | −0.44 |
| Mg0.47Zn0.53 | 0.4 | −0.93 | −0.33 | −0.48 |
| Mg0.47Zn0.52 | 0.42 | −0.95 | −0.27 | −0.49 |
| Mg0.49Zn0.51 | 0.42 | −0.92 | −0.09 | −0.53 |
| Mg0.51Zn0.49 | 0.44 | −0.91 | 0.08 | −0.56 |
| Mg0.53Zn0.47 | 0.46 | −0.9 | 0.3 | −0.6 |
| Mg0.56Zn0.44 | 0.49 | −0.88 | 0.62 | −0.66 |
| Mg0.58Zn0.42 | 0.51 | −0.85 | 0.86 | −0.7 |
| Mg0.61Zn0.39 | 0.54 | −0.8 | 1.23 | −0.76 |
| Mg0.72Zn0.28 | 0.64 | −0.56 | 2.6 | −0.96 |
| Mg0.74Zn0.26 | 0.66 | −0.5 | 2.89 | −1 |
| Mg0.81Zn0.19 | 0.71 | −0.26 | 3.79 | −1.11 |
| Mg0.83Zn0.17 | 0.73 | −0.19 | 4.06 | −1.15 |

To derive an optimum with respect to each of the parameters, an objective function is calculated according to the following formula:

F(x)=(G(x)−Gₜ)²+Al_{c}(x)−BIᵥ(x)+CE_{f}(x)

wherein G(x)=Δ-gap, I_{C}(x)=Δ-ISWO_{C}, I_{V}(x)=Δ-ISWO_{V}, and E_{f}(x)=Δ-E_{form}, each as a function of composition, i.e., amount of Mg and Zn. Herein, Gₜ is a target bandgap, and A, B, and C are weight factors. The optimum with respect to material properties corresponds to a minimum in F(x). Herein, for each of G t and weight factors A, B, and C, the following values were used: Gₜ: [0, 0.25, 0.5, 0.75, 1]; A: [0.1, 0.2]; B: [0.01, 0.02]; and C: [0.0, 0.5, 1.0, 1.5]. For all these 4×2×2×4 combinations, F(x) is optimized. All unique solutions are collected in Table A.

A minimum in F(x) corresponds to a balance between good electrical properties and good stability. According to the present calculations, these properties compare well with, and may be better than, the corresponding properties of InGaZnO₄, i.e., IGZO, that is at present generally used in the field of thin-film transistors. Embodiments of the disclosed technology correspond to mixed metal oxides having an amount of Mg and Zn close to that of the optimum.

### Example 2: Method for Forming the Mixed Metal Oxide

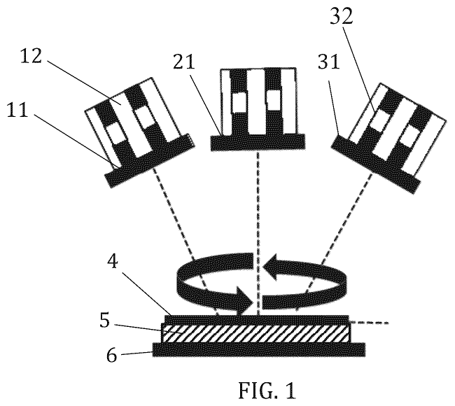

Reference is made to FIG. 1, which is a schematic representation of a combinatorial physical vapour deposition system that may be used for performing a method according to embodiments of the second aspect of the disclosed technology, to form a mixed metal oxide according to embodiments of the first aspect of the disclosed technology. The combinatorial physical vapour deposition system of this example may deposit oxides, for example, the primary oxides MgO and ZnO. For the deposition, in the example, two sputter targets 11, 21, and an optional third sputter target 31 are mounted, each on an individual cathode 12, 22, and 32. Each of the sputter targets 11, 21, and 31 is aimed towards a substrate 5. In this example, the substrate 5 is a 300 mm diameter Si wafer. Heating of the substrate 5 may be performed by clamping the substrate 5 to an electrically heated rotating chuck 6. The deposition is typically performed in an Ar atmosphere, although also other gases may be used. Ar may be ionized and accelerated towards each of the targets 11, 21, and 31, by application of a potential to each of the corresponding cathodes 12, 22, and 32. The impact of the Ar ions on a target 11, 21, or 31 induces a release of atoms or atom clusters from the target 11, 21, or 31. This process is referred to as “sputtering.”

Depending on the conductance of the target 11, 21, or 31, the potential applied to the cathode 12, 22, or 32 may be oscillated. When the target 11, 21, or 31 (if present) is an oxide material, for example, MgO or ZnO, the applied potential may oscillate at a frequency inside the radio frequency domain. When the target 11, 21, or 31 is an elemental target, for example, Mg, a DC potential may be applied. In this example, a MgO target 11 and a ZnO target 21 are powered with an oscillating potential, and an elemental Al target 31 is powered with a pulsed DC potential. Alternatively, a ZnO target 21 may be powered with an oscillating potential and an elemental Mg target 11 may be powered with a pulsed DC potential. To obtain a fully oxidized material with elemental targets, O₂ may be added to the sputtering gas. The O₂ gas may oxidize the target during the sputtering process, thereby forming an insulating top layer on the target. In that case, a pulsed DC potential may be preferably used. Pressure is regulated by the total flow, i.e., Ar flow and O₂ flow, and is typically in the range of a few, for example, 1 to 10, Pa.

In some embodiments, a uniform deposition, such as a uniform mixed metal oxide 4, may be achieved by optimization of the aiming angle of the cathodes 12, 22, and optionally 32, and by rotation of the substrate 5 at a high rate. Typically, a deposition rate is low enough to facilitate random mixing of the elements during deposition. Thereby, the deposition may result in a uniform film of the mixed metal oxide 4. The composition of the film 4, for example, the amounts of Zn and Mg in the mixed metal oxide 4, may be regulated by adjusting the potential that is applied to each cathode 12 and 22.

It is to be understood that although preferred embodiments, specific constructions, and configurations, as well as materials, have been discussed herein for devices according to the disclosed technology, various changes or modifications in form and detail may be made without departing from the scope of this invention. Steps may be added or deleted to methods described within the scope of the disclosed technology.

What is claimed is:

1. An amorphous mixed metal oxide comprising:
metal or metalloid elements comprising:
0.40 to 0.70 parts by mole Mg, 0.30 to 0.60 parts by mole Zn, and 0.00 to 0.30 parts by mole of other elements, selected from metals or metalloids,
wherein less than 0.01 parts by mole of the other elements is Al, and
wherein less than 0.04 parts by mole of the other elements is Ga;
oxygen; and
less than 0.01 parts by mole of non-metallic and non-metalloid impurities.

2. The oxide according to claim 1, wherein the parts by mole are as measured by Rutherford Backscattering Spectroscopy.

3. The oxide according to claim 1, consisting essentially of:
metal or metalloid elements consisting essentially of:
0.40 to 0.70 parts by mole Mg, 0.30 to 0.60 parts by mole Zn, and 0.00 to 0.30 parts by mole of other elements, selected from metals or metalloids,
wherein less than 0.01 parts by mole of the other elements is Al,
wherein less than 0.04 parts by mole of the other elements is Ga, and
wherein the sum of all parts by mole of Mg, Zn, and the other elements amounts to 1.00;
oxygen; and
less than 0.01 parts by mole of non-metallic and non-metalloid impurities.

4. The oxide according to claim 1, wherein the sum of all parts by mole of Mg, Zn, and the other elements amounts to about 1.

5. The oxide according to claim 1, wherein less than 0.001 parts by mole of the other elements is Al.

6. The oxide according to claim 1, wherein less than 0.01 part by mole of the other elements is Ga.

7. The oxide according to claim 1, wherein the metal or metalloid elements comprise 0.45 to 0.65 parts by mole Mg, 0.35 to 0.55 parts by mole Zn, and 0.00 to 0.20 parts by mole of the other elements selected from metals or metalloids.

8. The oxide according to claim 1, wherein the metal or metalloid elements comprise 0.53 to 0.57 parts by mole Mg, 0.43 to 0.47 parts by mole Zn, and 0.00 to 0.04 parts by mole of the other elements selected from metals and metalloids.

9. The oxide according to claim 1, wherein the oxygen is present in an amount that is within 10 mole % of a stoichiometric amount of the oxide.

10. The oxide according to claim 1, prepared by a process comprising depositing a magnesium oxide and a zinc oxide on a substrate, so as to form a mixed metal oxide, the mixed metal oxide comprising:
metal or metalloid elements comprising:
0.40 to 0.70 parts by mole Mg, 0.30 to 0.60 parts by mole Zn, and 0.00 to 0.30 parts by mole of other elements selected from metals or metalloids,
wherein less than 0.01 parts by mole of the other elements is Al, and
wherein less than 0.04 parts by mole of the other elements is Ga;
oxygen; and
less than 0.01 parts by mole of non-metallic and non-metalloid impurities.

11. The oxide according to claim 10, wherein the parts by mole are as measured by Rutherford Backscattering Spectroscopy.

12. The oxide according to claim 10, further comprising depositing one or more other oxides selected from metal oxides and metalloid oxides.

13. The oxide according to claim 10, wherein depositing is performed at a temperature of at most 400° C.

14. The oxide according to claim 10, wherein depositing is performed at a temperature range of 200° C. to 400° C.

15. The oxide according to claim 10, wherein the magnesium oxide and the zinc oxide are deposited using physical vapour deposition.

16. The oxide according to claim 15, wherein the physical vapour deposition is performed by sputtering using a magnesium oxide target and a zinc oxide target.

17. The oxide according to claim 16, wherein a first AC potential field is applied at a frequency of from 100 kHz to 10 MHz to at least one of the magnesium oxide target and the zinc oxide target.

18. The oxide according to claim 10, wherein the substrate comprises silicon.

19. A transistor comprising an amorphous mixed metal oxide, the mixed metal oxide comprising:
metal or metalloid elements comprising:
0.40 to 0.70 parts by mole Mg, 0.30 to 0.60 parts by mole Zn, and 0.00 to 0.30 parts by mole of other elements, selected from metals and metalloids,
wherein less than 0.01 parts by mole of the other elements is Al, and
wherein less than 0.04 parts by mole of the other elements is Ga;
oxygen; and
less than 0.01 parts by mole of non-metallic and non-metalloid impurities.

20. The transistor according to claim 19, wherein the amorphous mixed metal oxide forms a channel layer.

21. The transistor according to claim 19, wherein the transistor is a thin film transistor.
